(19) United States
(12) Patent Application Publication
(10) Pub. No.: US 2023/0357923 A1
(43) Pub. Date: Nov. 9, 2023

(54) FILM FORMING METHOD

(71) Applicant: Tokyo Electron Limited, Minato-ku, Tokyo (JP)

(72) Inventors: Kouji SHIMOMURA, Nirasaki-shi, Yamanashi (JP); Yoshihiro KATO, Nirasaki-shi, Yamanashi (JP); Toshio HASEGAWA, Nirasaki-shi, Yamanashi (JP); Junya SUZUKI, Nirasaki-shi, Yamanashi (JP)

(21) Appl. No.: 18/043,766

(22) PCT Filed: Aug. 30, 2021
(86) PCT No.: PCT/JP2021/031701

§ 371 Date: Mar. 2, 2023

(30) Foreign Application Priority Data
Sep. 10, 2020 (JP) 2020-151969

(51) Int. Cl. C23C 16/40; C23C 16/455; C23C 16/56; H01L 21/02

(52) U.S. Cl. CPC C23C 16/403; C23C 16/45553; C23C 16/56; H01L 21/0234; H01L 21/02178; H01L 21/0228

(57) ABSTRACT

A film forming method of forming a metal-containing aluminum oxide layer on a substrate having at least a metal layer on a surface thereof includes: a first operation of forming an aluminum oxide layer on the substrate with an aluminum-containing precursor and an oxidant; and a second operation of forming a metal oxide layer on the substrate with the oxidant and a precursor including a first metal other than aluminum. Assuming that a dielectric constant of only an oxide of the first metal is ε1 and a molar ratio of the first metal to all metals in the metal-containing aluminum oxide layer is X, the formed metal-containing aluminum oxide layer satisfies a following condition (1) or (2): X>⅓ and ε1<25×X/(3X−1) . . . (1); and X≤⅓. . . (2).

### TECHNICAL FIELD

The present disclosure relates to a film forming method.

### BACKGROUND

Patent Document 1 discloses a technology for forming an etching stop layer of an aluminum oxide, which is in contact with a dielectric layer and a metal layer, by reacting an aluminum-containing precursor with a reactant selected from a group consisting of alcohol and an aluminum alkoxide.

### PRIOR ART DOCUMENT

### Patent Document

Patent Document 1: Japanese Laid-Open Patent Publication No. 2018-085502

The present invention provides a technology for forming a film having etching resistance and capable of preventing moisture diffusion and metal diffusion.

### SUMMARY

A film forming method according to an aspect of the present disclosure is a film forming method of forming a metal-containing aluminum oxide layer on a substrate having at least a metal layer on a surface thereof. The film forming method includes a first operation and a second operation. The first operation forms an aluminum oxide layer on the substrate with an aluminum-containing precursor and an oxidant. The second operation forms a metal oxide layer on the substrate with the oxidant and a precursor including a first metal other than aluminum. In the film forming method, assuming that a dielectric constant of only an oxide of the first metal is ε1 and a molar ratio of the first metal to all metals in the metal-containing aluminum oxide layer is X, the formed metal-containing aluminum oxide layer satisfies a following condition (1) or (2):

X>⅓ and ε1<25×X/(3X−1) (1); and

X≤⅓ (2).

According to the present disclosure, it is possible to form a film having etching resistance and capable of preventing moisture diffusion and metal diffusion.

### BRIEF DESCRIPTION OF DRAWINGS

FIG. 1 is a diagram illustrating an example of a schematic configuration of a film forming apparatus according to an embodiment.

FIG. 2 is a diagram illustrating an example of a gas supply sequence when forming a metal-containing aluminum oxide layer by a film forming method according to an embodiment.

FIG. 3 is a diagram illustrating another example of the gas supply sequence when forming the metal-containing aluminum oxide layer by the film forming method according to an embodiment.

FIG. 4 is a diagram illustrating a comparison result of dry etching rates.

FIG. 5 is a diagram illustrating a comparison result regarding moisture diffusion and metal diffusion.

FIG. 6 is a diagram illustrating a schematic configuration of another example of the film forming apparatus according to an embodiment.

### DETAILED DESCRIPTION

Hereinafter, embodiments of a film forming method disclosed herein will be described in detail with reference to the drawings. In addition, the disclosed film forming method is not limited by the present embodiment.

In the manufacture of a semiconductor device, a dielectric layer formed on a metal wiring layer is patterned with a trench or a hole to form a contact for the metal wiring layer. An etching stop layer is formed on the metal wiring layer, for the purpose of protecting the metal wiring layer from etching of this patterning. An aluminum oxide, which is a film having etching selectivity, a high density, and a low dielectric constant, is generally used as the etching stop layer.

However, when the aluminum oxide is formed as the etching stop layer on the metal wiring layer, moisture diffusion or metal diffusion in the metal wiring layer may occur. When the moisture diffusion occurs, the low dielectric constant film around the etching stop layer deteriorates and the dielectric constant thereof increases. Further, leakage occurs when the metal diffusion occurs.

Therefore, a technology for forming a film having etching resistance and capable of preventing the moisture diffusion and the metal diffusion is necessary.

### Embodiment

### [Configuration of Film Forming Apparatus]

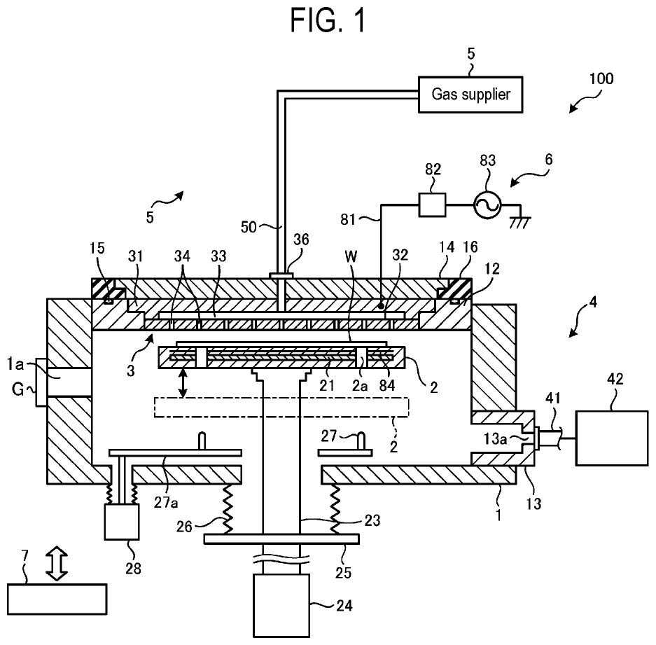

Embodiments will be described. First, a film forming apparatus 100 used for carrying out the film forming method according to an embodiment will be described. FIG. 1 is a diagram illustrating an example of a schematic configuration of the film forming apparatus 100 according to an embodiment. The film forming apparatus 100 illustrated in FIG. 1 is a capacitively coupled plasma processing apparatus. The film forming apparatus 100 includes a chamber 1, a susceptor 2 for horizontally supporting a substrate W inside the chamber 1, and a shower head 3 for supplying a processing gas into the chamber 1 in the form of a shower. Further, the film forming apparatus 100 includes an exhauster 4 for exhausting the interior of the chamber 1, a gas supplier 5 for supplying the processing gas to the shower head 3, a plasma generating mechanism 6, and a controller 7.

The chamber 1 is formed of a metal such as aluminum and has a substantially cylindrical shape. A loading/unloading port 1a for loading and unloading the substrate W is formed in a sidewall of the chamber 1. The loading/unloading port 1a may be opened and closed by a gate valve G. A dielectric ring 12 is provided in a top surface inner wall of the sidewall of the chamber 1. The dielectric ring 12 is formed of, for example, ceramics such as alumina (Al₂O₃). The dielectric ring 12 is a member that insulates the chamber 1 and the shower head 3. An exhaust duct 13 is provided in a lower portion of a main body of the chamber 1. The exhaust duct 13 is formed with an exhaust port 13a. A ceiling wall 14 is provided on an upper surface of the dielectric ring 12 so as to block an upper opening of the chamber 1. An insulation ring 16 is fitted around an outer periphery of the ceiling wall 14. A space between the insulating ring 16 and the dielectric ring 12 is hermetically sealed with a seal ring 15.

The susceptor 2 takes the form of a disc having a larger diameter than that of the substrate W and is supported by a support member 23. The susceptor 2 is formed of a ceramic material such as an aluminum nitride (AlN) or a metallic material such as an aluminum or a nickel-based alloy. A heater 21 for heating the substrate W is embedded in the susceptor 2. The heater 21 is powered with a heater power supply (not illustrated) to generate heat. Then, the heater power supply controls an output to the heater 21 in response to a temperature signal from a thermocouple (not illustrated) provided near a wafer placement surface on an upper surface of the susceptor 2, thereby controlling the substrate W to a predetermined temperature. Further, the susceptor 2 may be provided with a cooling medium flow path therein. The substrate W may be cooled to a predetermined temperature through the wafer placement surface by a cooling medium supply mechanism.

The support member 23 supporting the susceptor 2 extends downward of the chamber 1 from the center of a bottom surface of the susceptor 2 through a hole formed in a bottom wall of the chamber 1. A lower end of the support member 23 is connected to a lifting mechanism 24. The susceptor 2 may be moved up and down between a processing position illustrated in FIG. 1 and a transfer position (indicated by a one-dot dashed line in FIG. 1) under the processing position at which the transfer of the wafer is possible by the lifting mechanism 24 via the support member 23. Further, a flange member 25 is attached to a position of the support member 23 below the chamber 1. A bellows 26 is provided between a bottom surface of the chamber 1 and the flange member 25 to separate an atmosphere inside the chamber 1 from outside air. The bellows 26 expands and contracts as the susceptor 2 is moved up and down.

Three (only two are illustrated) water support pins 27 are provided in the vicinity of the bottom surface of the chamber 1 so as to protrude upward from a lifting plate 27a. The wafer support pins 27 may be moved up and down by a lifting mechanism 28 provided below the chamber 1 via the lifting plate 27a. The wafer support pins 27 are inserted through through-holes 2a provided in the susceptor 2 at the transfer position, and may protrude and retract to and from the upper surface of the susceptor 2. By moving the wafer support pins 27 up and down in this way, the substrate W is transferred between a wafer transfer mechanism (not illustrated) and the susceptor 2.

The shower head 3 is formed of a metal and is provided so as to face the susceptor 2. The shower head 3 is fixed to the ceiling wall 14 of the chamber 1. The shower head 3 has a main body part 31 having a gas diffusion space 33 therein.

A gas introduction hole 36 is formed in the center of an upper wall of the main body part 31 to extend to the gas diffusion space 33. Further, the gas introduction hole 36 is also continuously formed in the ceiling wall 14. A gas supply path 50 of the gas supplier 5 is connected to the gas introduction hole 36. A lower surface of the main body part 31 is configured of a shower plate 32 having a plurality of gas discharge holes 34. The processing gas introduced into the gas diffusion space 33 is discharged from the gas discharge holes 34 toward the substrate W.

The exhauster 4 includes an exhaust pipe 41 connected to the exhaust port 13a of the exhaust duct 13 and an exhaust mechanism 42 connected to the exhaust pipe 41 and having a vacuum pump, a pressure control valve, and the like. During processing, the gas inside the chamber 1 is exhausted from the exhaust duct 13 through the exhaust pipe 41 by the exhaust mechanism 42 of the exhauster 4.

The gas supplier 5 supplies various gases used for film formation to the gas supply path 50. For example, the gas supplier 5 supplies a raw material gas for film formation to the gas supply path 50. Further, the gas supplier 5 supplies a reactive gas, which reacts with a purge gas or a raw material gas, to the gas supply path 50. The gas supplied to the gas supply path 50 diffuses in the gas diffusion space 33 of the shower head 3 through the gas introduction hole 36, and is discharged from each gas discharge hole 34.

The plasma generating mechanism 6 is for plasmarizing the reactive gas when supplying the reactive gas and reacting it with the adsorbed raw material gas. The plasma generating mechanism 6 includes a feeder line 81 connected to the main body part 31 of the shower head 3, a matcher 82 and a radio frequency power supply 83 which are connected to the feeder line 81, and an electrode 84 embedded in the susceptor 2. The electrode 84 is grounded. When radio frequency power is supplied from the radio frequency power supply 83 to the shower head 3, a radio frequency electric field is created between the shower head 3 and the electrode 84, and plasma of the reactive gas is generated by the radio frequency electric field. The matcher 82 matches an interior (or output) impedance of the radio frequency power supply 83 with a load impedance including the plasma. The matcher 82 functions to enable the output impedance of the radio frequency power supply 83 to match with the load impedance when the plasma is generated inside the chamber 1.

The controller 7 includes a main controller, an input device, an output device, a display device, and a storage device. The main controller controls each component of the film forming apparatus 100 such as, for example, the heater power supply, the exhauster 4, the gas supplier 5, and the plasma generating mechanism 6. The main controller performs control using, for example, a computer (central processing unit (CPU)). The storage device stores parameters of various processings executed in the film forming apparatus 100. Further, a non-transient computer readable storage medium in which a program for controlling a processing executed in the film forming apparatus 100, that is, a processing recipe is stored in the storage device. The main controller calls a predetermined processing recipe stored in the storage medium, and controls the film forming apparatus 100 to perform a predetermined processing based on the processing recipe. The controller 7 controls each component of the film forming apparatus 100, thereby executing a processing of the film forming method according to an embodiment, which will be described later.

### [Film Formation of Etching Stop Layer]

Next, a flow of forming the etching stop layer by the film forming method according to an embodiment will be described. The film forming method according to the embodiment includes a preparation operation to prepare the substrate W which is a processing target. For example, in the preparation operation, the substrate W is transferred into the chamber 1 through the loading/unloading port 1a and is placed on the susceptor 2. The substrate W is, for example, a silicon substrate such as a semiconductor wafer. The substrate W has at least a metal layer on a surface thereof. A metal of the metal layer is, for example, copper (Cu) or zirconium (Zr). For example, the substrate W is formed on the surface thereof with a metal wiring layer as the metal layer. For the purpose of protecting the metal wiring layer from etching, a metal-containing aluminum oxide layer is formed as the etching stop layer on the metal wiring layer by the film forming method according to the embodiment.

After the preparation operation, the film forming apparatus 100 repeatedly performs a first operation of forming an aluminum oxide layer and a second operation of forming a metal oxide layer on the substrate W with a precursor containing a first metal other than aluminum and an oxidant to form a metal-containing aluminum oxide layer on the substrate W.

In the first operation, the aluminum oxide layer is formed on the substrate W with an aluminum-containing precursor and the oxidant. For example, in the first operation, the aluminum-containing precursor and the oxidant are alternately supplied into the chamber 1 to form the aluminum oxide layer by atomic layer deposition (ALD).

The aluminum-containing precursor is any of an aluminum hydride, trimethylaluminum, triethylaluminum, tripropylaluminum, and triisopropoxyaluminum. An aluminum oxide uses, for example, trialkyl aluminum having an alkyl group of 3 or less carbon atoms, trialkoxy aluminum, and trihalogenated aluminum as an aluminum raw material.

The oxidant is any of water (H₂O), a hydrogen peroxide (H₂O₂), oxygen (O₂), ozone (O₃), oxygen plasma (plasma O), oxygen radicals (radical O), and isopropyl alcohol (alcohol(R—OH) R=CₘH₂ₘ₊₁, m=0 to 4). When forming the metal-containing aluminum oxide layer by thermal ALD, oxygen, ozone, water, a hydrogen peroxide, oxygen radicals, or alcohol(R—OH)(R=CₘH₂ₘ₊₁, m=0 to 4) may be used as the oxidant. When forming the metal-containing aluminum oxide layer by plasma ALD, oxygen, ozone, water, a hydrogen peroxide, oxygen radicals, oxygen plasma, or alcohol(R—OH)(R=CₘH₂ₘ₊₁, m=0 to 4) may be used as the oxidant.

In the second operation, the metal oxide layer is formed on the substrate W with the precursor containing the first metal other than aluminum and the oxidant. For example, in the second operation, the first metal-containing precursor and the oxidant are alternately supplied to form the metal oxide layer by ALD.

The first metal-containing precursor is an organometallic compound of hafnium (Hf), magnesium (Mg), manganese (Mn), silicon (Si), tantalum (Ta), or zinc (Zn). As for zinc, for example, a raw material is dialkyl zinc having an alkyl group of 3 or less carbon atoms. As for silicon, for example, a raw material is alkyl silicon having an alkyl group of 0 to 3 carbon atoms, amide silicon, and silicon halide. As for manganese, for example, a raw material is biscyclopentadienyl derivative manganese, carbonyl manganese, and ligand-exchanged ones of the above, trisamidinate derivative manganese having an alkyl group of 5 or less carbon atoms, and tetrakis β-diketonato manganese having an alkyl group of 4 or less carbon atoms. As for magnesium, for example, a raw material is biscyclopentadienyl derivative magnesium, bisamide magnesium having an alkyl group of 3 or less carbon atoms, and ligand-exchanged ones of the above, trisamidinate derivative magnesium having an alkyl group of 5 or less carbon atoms, and tetra βmagnesium having an alkyl group of 4 or less carbon atoms. As for tantalum, for example, a raw material is pentaalkoxy tantalum having an alkyl group of 3 or less carbon atoms, trisamideimide tantalum having an alkyl group of 4 or less carbon atoms, and pentahalogenated tantalum. As for hafnium, for example, a raw material is tetraalkoxy hafnium having an alkyl group of 4 or less carbon atoms, tetrakisamide hafnium having an alkyl group of 3 or less carbon atoms, trisamide pentadienyl derivative hafnium, and tetrahalide hafnium. In addition, when alkyl groups exist in a plurality of molecules, they may take the same number of carbon atoms, or a part or the entirety of them may take different numbers of carbon atoms within a range of carbon atoms.

The oxidant is any of water (H₂O), a hydrogen peroxide (H₂O₂), oxygen (O₂), ozone (O₃), oxygen plasma (plasma O), oxygen radicals (radical O), and isopropyl alcohol (alcohol(R—OH) R=CₘH₂ₘ₊₁, m=0 to 4). When forming the metal-containing aluminum oxide layer by thermal ALD, oxygen, ozone, water, a hydrogen peroxide, oxygen radicals, and alcohol(R—OH)(R=CₘH₂ₘ₊₁, m=0 to 4) may be used as the oxidant. When forming the metal-containing aluminum oxide layer by plasma ALD, oxygen, ozone, water, a hydrogen peroxide, oxygen radicals, oxygen plasma, and alcohol(R—OH)(R=CₘH₂ₘ₊₁, m=0 to 4) may be used as the oxidant.

The film forming apparatus 100 may change a molar ratio X of the first metal in the formed metal-containing aluminum oxide layer, or a dielectric constant of the metal-containing aluminum oxide layer by changing the number of times in which the first operation and the second operation are performed, respectively.

In the film forming apparatus 100, assuming that the dielectric constant of only an oxide of the first metal is £ 1 and the molar ratio of the first metal in the metal-containing aluminum oxide layer is X, the metal-containing aluminum oxide layer is formed so as to satisfy the following condition (1) or (2).

X>⅓ and ε1<25×X/(3X−1) (1); and

X≤⅓ (2).

Here, X is the molar ratio of the first metal to all metals in the metal-containing aluminum oxide layer.

ε1 is the dielectric constant of only the oxide of the first metal.

The molar ratio X of the first metal in the metal-containing aluminum oxide layer is obtained from the following equation (3).

X=M1/(M2+M1) (3)

Here, M1 is a substance amount of the oxide of the first metal in the metal-containing aluminum oxide layer.

M2 is a substance amount of the aluminum oxide in the metal-containing aluminum oxide layer.

The film forming apparatus 100 may perform a modification operation of modifying a surface of the film formed in the first operation and the second operation. In the modification operation, a plasma processing is appropriately used for modifying the surface such as increasing adsorbability of the film or increasing a density of the film. For example, in the modification operation, a surface treatment of supplying any of an NH₃ gas, an H₂ gas, and an Ar gas and generating plasma to modify the surface of the substrate W by the plasma is performed.

Next, a specific example of forming the metal-containing aluminum oxide layer will be described.

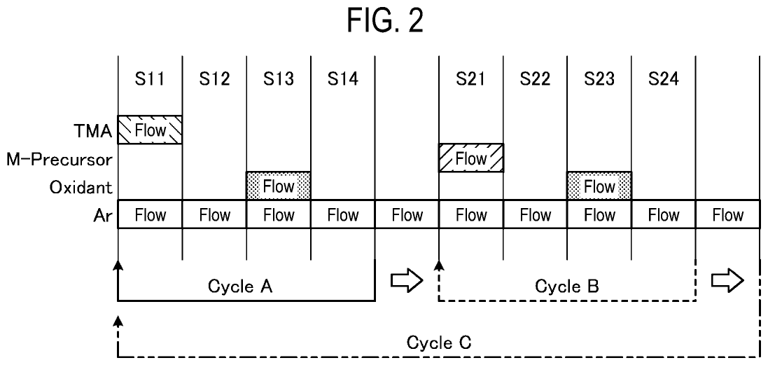

FIG. 2 is a diagram illustrating an example of a gas supply sequence when forming the metal-containing aluminum oxide layer by the film forming method according to an embodiment. The controller 7 controls the heater 21 of the susceptor 2 to heat the substrate W to a predetermined temperature. The temperature of the substrate W is set to 400 degrees C. or lower, for example, 200 degrees C. to 350 degrees C., in order to protect the metal layer serving as a wiring. Further, the controller 7 controls a vacuum pump or a pressure control valve of the exhaust mechanism 42 to adjust the interior of the chamber 1 to a predetermined pressure. The internal pressure of the chamber 1 is, for example, 3 Torr to 10 Torr.

The controller 7 controls the gas supplier 5 to continuously supply an Ar gas from the gas supplier 5 during the gas supply sequence of film formation. Further, the controller 7 controls the gas supplier 5 to supply a gas of the aluminum-containing precursor from the gas supplier 5 (step S11). The aluminum-containing precursor is trimethylaluminum (TMA). The Ar gas is supplied at a relatively high flow rate, for example, at a flow rate greater than that of a TMA gas. Thus, the aluminum-containing precursor is adsorbed onto the surface of the substrate W.

The controller 7 controls the gas supplier 5 to stop the supply of the gas of the aluminum-containing precursor (step S12). Since the Ar gas is continuously supplied, the gas of the aluminum-containing precursor inside the chamber 1 is purged by the Ar gas.

The controller 7 controls the gas supplier 5 to supply a gas of the oxidant from the gas supplier 5 (step S13). The oxidant is H₂O or alcohol(R—OH)(R=CₘH₂ₘ₊₁, m=0 to 4). Thus, the aluminum-containing precursor adsorbed onto the surface of the substrate W is oxidized, so that the aluminum oxide is formed.

The controller 7 controls the gas supplier 5 to stop the supply of the oxidant gas (step S14). Since the Ar gas is continuously supplied, the oxidant gas inside the chamber 1 is purged by the Ar gas.

Cycle A of these steps S11 to S14 corresponds to the first operation of forming the aluminum oxide layer. The controller 7 forms the aluminum oxide layer having a desired thickness by repeating Cycle A of steps S11 to S14. The controller 7 repeats Cycle A of steps S11 to S14 a first number of times so that the aluminum oxide layer has a desired thickness.

When Cycle A is completely performed the first number of times, the controller 7 controls the gas supplier 5 to supply a gas of the first metal-containing precursor (M-Precursor) from the gas supplier 5 (step S21). The first metal-containing precursor is Mg. Thus, the first metal-containing precursor is adsorbed onto the surface of the substrate W.

The controller 7 controls the gas supplier 5 to stop the supply of the gas of the first metal-containing precursor (step S22). Since the Ar gas is continuously supplied, the gas of the first metal-containing precursor inside the chamber 1 is purged by the Ar gas.

The controller 7 controls the gas supplier 5 to supply the gas of the oxidant from the gas supplier 5 (step S23). The oxidant is H₂O or alcohol(R—OH)(R=CₘH₂ₘ₊₁, m=0 to 4). Thus, the gas of the first metal-containing precursor adsorbed onto the surface of the substrate W is oxidized, so that the metal oxide layer of the first metal is formed.

The controller 7 controls the gas supplier 5 to stop the supply of the oxidant gas (step S24). Since the Ar gas is continuously supplied, the oxidant gas inside the chamber 1 is purged by the Ar gas.

Cycle B of these steps S21 to S24 corresponds to the second operation of forming the metal oxide layer. The controller 7 forms the metal oxide layer having a desired thickness by repeating Cycle B of steps S21 to S24. The controller 7 repeats Cycle B of steps S21 to S24 a second number of times so that the metal oxide layer has a desired thickness.

The controller 7 alternately repeats steps S11 to S14 and steps S21 to S24 to form the metal-containing aluminum oxide layer composed of the aluminum oxide layer and the metal oxide layer. As described above, the controller 7 forms the metal-containing aluminum oxide layer by repeating steps S11 to S14 the first number of times, and then repeating steps S21 to S24 the second number of times. For example, the controller 7 forms the metal-containing aluminum oxide layer by repeating steps S21 to S24 once every time steps S11 to S14 are repeated any of one to five times (for example, five times). The controller 7 forms the metal-containing aluminum oxide layer having a desired thickness by repeating Cycle C, which includes Cycle A of steps S11 to S14 and Cycle B of steps S21 to S24.

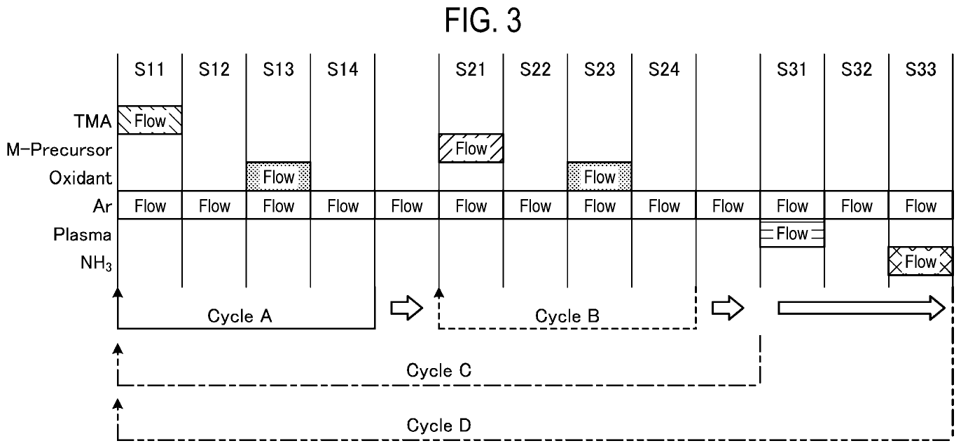

In addition, the film forming method according to an embodiment may implement the modification operation. FIG. 3 is a diagram illustrating another example of the gas supply sequence when forming the metal-containing aluminum oxide layer by the film forming method according to an embodiment. FIG. 3 illustrates the gas supply sequence in a case of including the modification operation. Steps S11 to S14 and steps S21 to S24 are the same as those in FIG. 2, and therefore, descriptions thereof will be omitted.

When Cycle B is completely performed the second number of times, the controller 7 controls the radio frequency power supply 83 to supply radio frequency power having a predetermined frequency from the radio frequency power supply 83 to the shower head 3 and generate plasma of the Ar gas in the processing space to perform the surface treatment of modifying the surface of the substrate W (step S31). The frequency of the applied radio frequency power is in a range of 450 KHz to 60 MHz, for example, 40 MHz. This may increase adsorbability of the film and increase the density of the film.

The controller 7 controls the radio frequency power supply 83 to stop the supply of the radio frequency power (step S32). Then, the controller 7 controls the gas supplier 5 to supply an NH₃ gas from the gas supplier 5 to perform a treatment of the surface (step S33).

These steps S31 to S33 correspond to the modification operation.

The controller 7 performs steps S31 and S32 every time Cycle C is performed a predetermined number of times to form the metal-containing aluminum oxide layer. The controller 7 forms the metal-containing aluminum oxide layer having a desired thickness by repeating Cycle D, which includes Cycle C and steps S31 and S32. In addition, steps S31 to S33 may be performed only once at the end. Further, step S31 may be performed every time Cycle C is performed the predetermined number of times, and step S33 may be performed only once at the end. Further, step S33 may not be performed.

In the gas supply sequence illustrated in FIGS. 2 and 3, the aluminum oxide layer is formed by Cycle A of steps S11 to S14, and the metal oxide layer is formed by Cycle B of steps S21 to S24. In the gas supply sequence, a content of the metal oxide layer in the metal-containing aluminum oxide layer may be controlled by changing the number of implementation of Cycles A and B.

Semiconductor devices manufactured on the substrate W are becoming finer. The metal-containing aluminum oxide layer formed as the etching stop layer needs to have a dielectric constant of 12 or less because it is necessary to keep an electric field strength below a certain level with a film thickness of 10 nm or less. In order to achieve the dielectric constant to 12 or less with the film thickness of 10 nm or less, the film forming method according to an embodiment forms the metal-containing aluminum oxide layer so as to satisfy the above-described condition (1) or (2). An example of a raw material of the metal oxide layer, which satisfies the above-described condition (1) or (2), has a high vapor pressure and is easily available, may be the organometallic compound of Hf, Mg, Mn, Si, Ta, or Zn described above.

As described above, when the aluminum oxide layer is formed as the etching stop layer on the metal wiring layer, moisture diffusion or metal diffusion in the metal wiring layer may occur. When moisture diffusion occurs, the low dielectric constant film around the etching stop layer deteriorates and the dielectric constant thereof increases. Further, leakage occurs when metal diffusion occurs.

Therefore, the film forming method according to an embodiment forms the metal-containing aluminum oxide layer by adding a metal oxide film having excellent resistance against moisture diffusion or metal diffusion to the aluminum oxide. Thus, the metal-containing aluminum oxide layer may have etching resistance and prevent diffusion of moisture and diffusion of a wiring metal and an electrode metal from the outside into the metal layer.

In addition, in the above embodiment, a case where metal oxide layers are contained at the same ratio in a thickness direction of the metal-containing aluminum oxide layer has been described as an example. However, the present disclosure is not limited to this. The ratio of the metal oxide layers may vary in the thickness direction of the metal-containing aluminum oxide layer. For example, film formation may be such that the amount of the aluminum oxide is increased on the side of the metal layer of the substrate W. For example, when forming the metal-containing aluminum oxide layer by repeating Cycle C, the controller 7 may perform Cycle A more times or Cycle B less times in a lower portion on the side of the metal layer than in an upper portion.

Further, the metal-containing aluminum oxide layer may be such that the aluminum oxide is formed at an interface from the viewpoint of adhesion with the metal layer or the dielectric layer of the substrate W. For example, the controller 7 may first perform Cycle A in the film formation of the metal-containing aluminum oxide layer. Further, the controller 7 may perform Cycle A after the last cycle C.

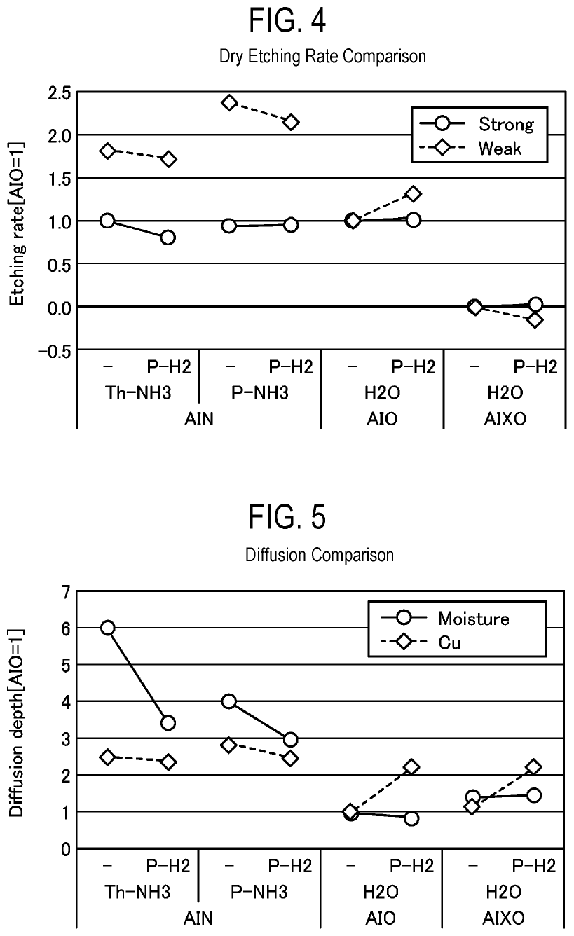

Next, a specific example of a film formation result will be described. FIG. 4 is a diagram illustrating a comparison result of dry etching rates. FIG. 5 is a diagram illustrating a comparison result regarding moisture and metal diffusion. In FIGS. 4 and 5, “AlXO” is the metal-containing aluminum oxide layer formed by the film forming method according to an embodiment. The aluminum-containing precursor was trimethylaluminum, the oxidant gas was H₂O, and the first metal-containing precursor was bisethylcyclopentadienylmagnesium. “−” is a result of not performing the modification operation, and “P—H₂” is a result of performing the surface treatment of modifying the surface of the substrate W with plasma of an H₂ gas. FIGS. 4 and 5 illustrate “AlO” and “AlN” as comparative examples. “AlO” is the aluminum oxide layer formed by ALD. The aluminum-containing precursor was trimethylaluminum, and the oxidant gas was H₂O. “−” is a result of not performing the modification operation, and “P—H₂” is a result of performing the surface treatment of modifying the surface of the substrate W with plasma of the H₂ gas. “AlN” is an aluminum nitride layer formed by ALD. The aluminum-containing precursor was trimethylaluminum, and a nitriding agent gas was NH₃. “Th—NH3” is a result of forming the aluminum nitride layer by thermal ALD, and “P—NH₃” is a result of forming the aluminum nitride layer by plasma ALD. Each “−” is a result of not performing the modification operation, and “P—H₂” is a result of performing the surface treatment of modifying the surface of the substrate W with the plasma of the H₂ gas.

In the manufacture of semiconductor devices, when the dielectric layer is thick, etching is performed under a strong etching condition. When the dielectric layer is thinned by etching, etching is performed under a weak etching condition. In FIG. 4, “Strong” is an etching rate obtained by etching under the strong etching condition. “Weak” is an etching rate obtained by etching under the weak etching condition. Both the etching rates “Strong” and “Weak” are indicated by values obtained by normalizing a value of an etching rate of “−” of “AlO” as 1, respectively.

In FIG. 4, as indicated by “AlXO”, the metal-containing aluminum oxide layer formed by the film forming method according to an embodiment has sufficient etching resistance due to a low etching rate. In addition, it is considered that the reason for the etching rate being a negative value in “P—H₂” of “Weak” of “AlXO” is that the metal-containing aluminum oxide layer was hardly etched, and the film thickness increased due to adhesion of a surrounding etched product.

In FIG. 5, “Moisture” is a diffusion depth of moisture in the metal layer. A metal of the metal layer is Cu. “Cu” is a diffusion depth of the metal layer. Both “Moisture” and “Cu” are indicated by values obtained by normalizing a value of a diffusion depth in “−” of “AlO” as 1, respectively.

In FIG. 5, as indicated by “AlXO”, the metal-containing aluminum oxide layer formed by the film forming method according to an embodiment is more prevented from moisture diffusion and metal diffusion than “AlN”. Further, the metal-containing aluminum oxide layer is illustrated as having an effect of preventing moisture diffusion and metal diffusion equivalent to that of “AlO”.

As described above, the film forming method according to an embodiment may form a film having etching resistance and capable of preventing moisture diffusion and metal diffusion.

As described above, the film forming method according to an embodiment forms the metal-containing aluminum oxide layer on the substrate W having at least the metal layer on the surface thereof. The film forming method includes the first operation (steps S11 to S14) and the second operation (steps S21 to S24). The first operation forms the aluminum oxide layer on the substrate W with the aluminum-containing precursor and the oxidant. The second operation forms the metal oxide layer on the substrate W with the precursor containing the first metal other than aluminum and the oxidant. In the film forming method, assuming that the dielectric constant of only an oxide of the first metal is ε1 and the molar ratio of the first metal to all metals in the metal-containing aluminum oxide layer is X, the formed metal-containing aluminum oxide layer satisfies the above-described condition (1) or (2). Thus, the film forming method according to the embodiment may form the film having etching resistance and capable of preventing moisture diffusion and metal diffusion.

Further, the film forming method further includes the modification operation (steps S31 to S33). The modification operation modifies the surface of the film formed in the first operation and the second operation. Thus, the adsorbability of the film may be increased, and the density of the film may be increased.

Further, the first operation forms the aluminum oxide layer by alternately supplying the aluminum-containing precursor and the oxidant. Thus, the aluminum oxide layer may be formed. The second operation forms the metal oxide layer by alternately supplying the first metal-containing precursor and the oxidant. Thus, the metal oxide layer may be formed.

Further, the dielectric constant of the formed metal-containing aluminum oxide layer is 12 or less. Thus, even when the thickness of the metal-containing aluminum oxide layer is 10 nm or less, the electric field strength below a certain level may be maintained.

Further, the metal-containing aluminum oxide layer is formed by alternately repeating the first operation and the second operation. Thus, the metal-containing aluminum oxide layer having a desired film thickness may be formed.

Further, in the film formation of the metal-containing aluminum oxide layer, the first operation is performed first. Adhesion to the metal layer on the surface of the substrate W may be enhanced.

Although the embodiments have been described above, it should be noted that the embodiments disclosed herein are exemplary in all respects and are not restrictive. In fact, the above-described embodiments may be implemented in various forms. Further, the above-described embodiments may be omitted, replaced or modified in various forms without departing from the scope and spirit of the appended claims.

For example, in the above embodiment, a case where the film forming apparatus of the present disclosure is a single chamber type film forming apparatus 100 having one chamber has been described as an example. However, the present disclosure is not limited to this. The film forming apparatus of the present disclosure may be a multi-chamber type film forming apparatus having a plurality of chambers.

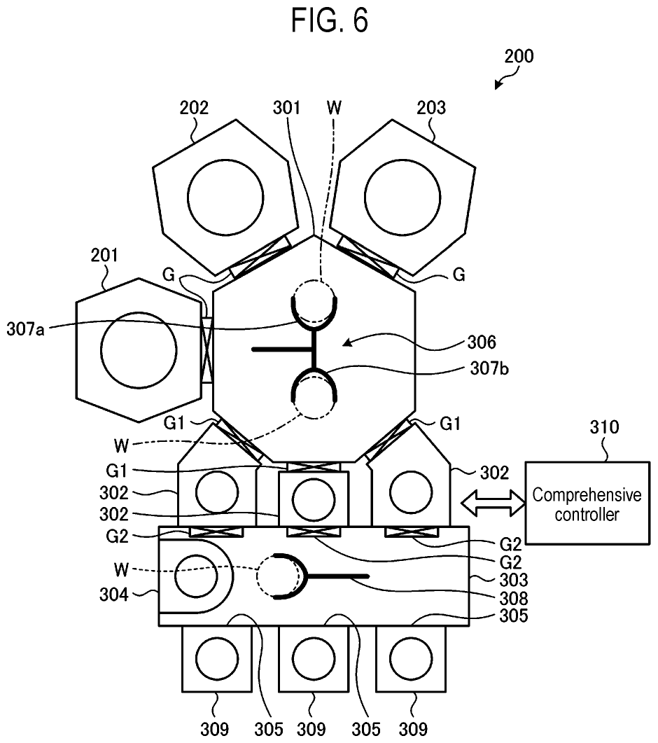

FIG. 6 is a diagram illustrating another example of a schematic configuration of a film forming apparatus 200 according to an embodiment. As illustrated in FIG. 6, the film forming apparatus 200 is a multi-chamber type film forming apparatus having three chambers 201 to 203. The film forming apparatus 200 performs the film forming method according to an embodiment using the three chambers 201 to 203.

The chambers 201 to 203 are connected via gate valves G to three walls of a vacuum transfer chamber 301 having a polygonal (for example, heptagonal) planar shape, respectively. The interior of the vacuum transfer chamber 301 is exhausted by a vacuum pump and is maintained at a predetermined degree of vacuum. Three load lock chambers 302 are connected to other three walls of the vacuum transfer chamber 301 via gate valves G1. An atmospheric transfer chamber 303 is provided on the opposite side of the vacuum transfer chamber 301 with the load lock chambers 302 interposed therebetween. The three load lock chambers 302 are connected to the atmospheric transfer chamber 303 via gate valves G2. The load lock chambers 302 control the pressure between an atmospheric pressure and a vacuum when transferring the substrate W between the atmospheric transfer chamber 303 and the vacuum transfer chamber 301.

Three ports 305 for installation of carriers (for example, FOUPs) 309 in which the substrates W are accommodated are provided on a wall of the atmospheric transfer chamber 303 opposite to a wall to which the load lock chambers 302 are installed. Further, an alignment chamber 304 in which the substrates W are aligned is provided on a sidewall of the atmospheric transfer chamber 303. A down-flow of clean air is created in the atmospheric transfer chamber 303.

A transfer mechanism 306 is provided in the vacuum transfer chamber 301. The transfer mechanism 306 transfers the substrate W to and from the chambers 201 to 203 and the load lock chambers 302. The transfer mechanism 306 includes two independently movable transfer arms 307a and 307b.

A transfer mechanism 308 is provided in the atmospheric transfer chamber 303. The transfer mechanism 308 transfers the substrate W to and from the carriers 309, the load lock chambers 302, and the alignment chamber 304.

The film forming apparatus 200 includes a controller 310. An operation of the film forming apparatus 200 is comprehensively controlled by the controller 310.

The film forming apparatus 200 configured as described above performs, a part or the entirety of the first operation, the second operation, and the modification operation of the film forming method according to an embodiment in the three chambers 201 to 203 in a dispersed manner. For example, the film forming apparatus 200 performs the first operation of steps S11 to S14 illustrated in FIG. 3 in the chamber 201. Further, the film forming apparatus 200 performs the second operation of steps S21 to S24 in the chamber 202. Further, the film forming apparatus 200 performs the modification operation of steps S31 to S33 in the chamber 203. As described above, the film forming method according to an embodiment may be performed in the multi-chamber type film forming apparatus.

In addition, it should be noted that the embodiments disclosed herein are exemplary in all respects and are not restrictive. In fact, the above-described embodiments may be implemented in various forms. Further, the above-described embodiments may be omitted, replaced, or modified in various forms without departing from the scope and spirit of the appended claims.

### EXPLANATION OF REFERENCE NUMERALS

W: substrate, 1: chamber, 2: susceptor, 3: shower head, 5: gas supplier, 7: controller, 83: radio frequency power supply, 100: film forming apparatus, 200: film forming apparatus, 201 to 203: chambers

1-14. (canceled)

15. A film forming method of forming a metal-containing aluminum oxide layer on a substrate having at least a metal layer on a surface thereof, the method comprising:
a first operation of forming an aluminum oxide layer on the substrate with an aluminum-containing precursor and an oxidant; and
a second operation of forming a metal oxide layer on the substrate with the oxidant and a precursor including a first metal other than aluminum,
wherein, assuming that a dielectric constant of only an oxide of the first metal is ε1 and a molar ratio of the first metal to all metals in the metal-containing aluminum oxide layer is X, the formed metal-containing aluminum oxide layer satisfies a following condition (1) or (2):
X>⅓ and ε1<25×X/(3X−1) (1); and
X≤⅓ (2).

16. The film forming method of claim 15, further comprising a modification operation of modifying a surface of the film formed in at least one of the first operation or the second operation.

17. The film forming method of claim 16, wherein the first operation forms the aluminum oxide layer by alternately supplying the aluminum-containing precursor and the oxidant.

18. The film forming method of claim 17, wherein the second operation forms the metal oxide layer by alternately supplying the precursor including the first metal and the oxidant.

19. The film forming method of claim 18, wherein the dielectric constant of the formed metal-containing aluminum oxide layer is 12 or less.

20. The film forming method of claim 19, wherein the metal-containing aluminum oxide layer is formed by alternately repeating the first operation and the second operation.

21. The film forming method of claim 20, wherein the first operation is first performed in film formation of the metal-containing aluminum oxide layer.

22. The film forming method of claim 21, wherein the aluminum-containing precursor is any of an aluminum hydride, trimethylaluminum, triethylaluminum, tripropylaluminum, and triisopropoxyaluminum.

23. The film forming method of claim 22, wherein the oxidant is any of H₂O, H₂O₂, O₂, O₃, plasma O, radical O, and isopropyl alcohol.

24. The film forming method of claim 23, wherein the precursor including the first metal is an organometallic compound of Hf, Mg, Mn, Si, Ta, or Zn.

25. The film forming method of claim 24, wherein a metal of the metal layer is Cu or Zr.

26. The film forming method of claim 16, wherein the modification operation is performed using plasma of at least any of an NH₃ gas, an H₂ gas, and an Ar gas.

27. The film forming method of claim 16, wherein the modification operation is performed for each specific cycle of the first operation and the second operation.

28. The film forming method of claim 16, wherein the modification operation is performed for each specific cycle of the first operation.

29. The film forming method of claim 15, wherein the first operation forms the aluminum oxide layer by alternately supplying the aluminum-containing precursor and the oxidant.

30. The film forming method of claim 15, wherein the second operation forms the metal oxide layer by alternately supplying the precursor including the first metal and the oxidant.

31. The film forming method of claim 15, wherein the dielectric constant of the formed metal-containing aluminum oxide layer is 12 or less.

32. The film forming method of claim 15, wherein the metal-containing aluminum oxide layer is formed by alternately repeating the first operation and the second operation.

33. The film forming method of claim 15, wherein the aluminum-containing precursor is any of an aluminum hydride, trimethylaluminum, triethylaluminum, tripropylaluminum, and triisopropoxyaluminum.

34. The film forming method of claim 15, wherein the oxidant is any of H₂O, H₂O₂, O₂, O₃, plasma O, radical O, and isopropyl alcohol.
